(19) United States
(12) Patent Application Publication
(10) Pub. No.: US 2020/0053871 A1
(43) Pub. Date: Feb. 13, 2020

(54) PRINTED CIRCUIT BOARD DEVICE FOR AN IMAGE CAPTURE MODULE FOR A CAMERA, IMAGE CAPTURE MODULE THAT INCLUDES A PRINTED CIRCUIT BOARD DEVICE, AND METHOD FOR MANUFACTURING A PRINTED CIRCUIT BOARD DEVICE

(71) Applicant: Robert Bosch GmbH, Stuttgart (DE)

(72) Inventors: Johannes Eschler, Weil Der Stadt (DE); Martin Winkler, Sonthofen (DE)

(21) Appl. No.: 16/531,391

(22) Filed: Aug. 5, 2019

(30) Foreign Application Priority Data
Aug. 7, 2018 (DE) 102018213146.5

(51) Int. Cl. H05K 1/02; H01L 27/146; H05K 1/03; H05K 3/24

(52) U.S. Cl. CPC H05K 1/0271; H01L 27/14601; H05K 3/24; H05K 1/0346; H05K 1/0306

(57) ABSTRACT

A printed circuit board device for an image capture module for a camera. The printed circuit board device includes a printed circuit board, an image sensor, and at least one copper layer and/or carbon layer. The printed circuit board includes a first main surface and a second main surface opposite from the first main surface. The image sensor is or may be situated on the first main surface of the printed circuit board. The copper layer that contains copper at least in part, and/or the carbon layer that contains carbon at least in part, are/is situated on the second main surface and formed for stabilization of the printed circuit board.

### CROSS REFERENCE

The present application claims the benefit under 35 U.S.C. § 119 of German Patent Application No. DE 102018213146.5 filed on Aug. 7, 2018, which is expressly incorporated herein by reference in its entirety.

### FIELD

The present invention is directed to a printed circuit board device, a method, and a computer program for manufacturing the printed circuit board device.

### BACKGROUND INFORMATION

A common material for a flexible printed circuit board is a printed circuit board on a stainless steel substrate or a so-called FR4 printed circuit board made from a flame-retardant composite composed of epoxy resin and glass fiber fabric.

Korean Patent KR 19980060521 U describes a printed circuit board with boreholes for protection from bending in some areas.

### SUMMARY

The present invention provides a printed circuit board device for an image capture module for a camera, an image capture module that includes a printed circuit board device, and a method for manufacturing a printed circuit board device. Advantageous refinements and improvements of the printed circuit board device are described herein.

Advantages that are achievable with the presented approach include that a printed circuit board device is provided for which the printed circuit board is not bent, or is only slightly bent, with changes in temperature or moisture. When this type of printed circuit board device is used with an image recorder of a camera, a necessary sharpness corridor of a lens in the image recorder may advantageously be provided, so that an image sensor on the printed circuit board is always situated in an area of sufficiently high sharpness.

A printed circuit board device for an image capture module for a camera includes a printed circuit board, an image sensor, and at least one copper layer and/or carbon layer. The printed circuit board includes a first main surface and a second main surface opposite from the first main surface. The first main surface may be situated extending in parallel to the second main surface. The image sensor is or may be situated on the first main surface of the printed circuit board. The copper layer that contains copper at least in part and/or a carbon layer that contains carbon at least in part are/is situated on the second main surface and formed for stabilization of the printed circuit board.

A surface of an element that is largest compared to other possible surfaces is understood as a main surface. Accordingly, a length that is largest compared to other lengths is understood as a main length or a main extension length.

An image capture module, also referred to as an imager module, is used in a camera as an image recording unit that converts an optical signal into an electrical signal. The image capture module may include a lens for optical imaging, and an image sensor that is supported and/or contacted by a printed circuit board. A connecting element, referred to as the lens holder, may be situated between the lens and the image sensor. As the result of thermal expansion and/or absorption of moisture by one or multiple elements of the image capture module, the printed circuit board may warp, thus changing a distance between the lens and the image sensor, so that in turn, an image sharpness may no longer be sufficient for an image representation or an image processing algorithm. Due to the copper and/or carbon layer, the printed circuit board device presented here advantageously counteracts such warping of the printed circuit board.

The printed circuit board may also include at least one through opening from the first main surface to the second main surface. This through opening may be situated extending transversely with respect to one or both of the two main surfaces of the printed circuit board. A width of the through opening that extends in the first main surface and/or further main surface may correspond to a length or width of the image sensor. Such a through opening may locally weaken the printed circuit board. It is now particularly advantageous when, according to one specific embodiment, the printed circuit board includes at least one further through opening from the first main surface to the second main surface, it being possible in particular for a first intermediate section of the first main surface between the through opening and the further through opening to be at least partially contacted by the image sensor, and/or for a second intermediate section of the second main surface between the through opening and the further through opening to be at least partially contacted by the copper layer and/or carbon layer.

Edge areas outside the through openings or the image sensor, each situated opposite from the intermediate sections, may thus be decoupled from warping, and maintain their original shape even in the event of thermal expansion and/or absorption of moisture. A contribution to defocusing may thus be reduced by the one or multiple through opening(s).

However, according to one specific embodiment, when the image sensor and/or the copper layer and/or carbon layer are/is glued to the printed circuit board, in addition the first intermediate section may be at least partially contacted by a first adhesive layer between the image sensor and the first main surface, and/or the second intermediate section may be at least partially contacted by a second adhesive layer between the copper layer and/or carbon layer and the second main surface.

A first coefficient of expansion of the printed circuit board may be greater than a second coefficient of expansion of the copper layer and/or carbon layer. Increased rigidity of the copper layer and/or carbon layer compared to the printed circuit board, and thus an overall higher rigidity of the printed circuit board device compared to the printed circuit board, may be ensured in this way. For example, the image sensor, for example a material of the image sensor, may have a coefficient of thermal expansion of 6 parts per million (ppm) within a tolerance range of up to 10 or 20 percent deviation. The printed circuit board, for example a material of the printed circuit board, may have a coefficient of thermal expansion of 25 ppm within a tolerance range of up to 10 or 20 percent deviation. The copper layer, for example a material of the copper layer, may have a coefficient of thermal expansion of 16 ppm within a tolerance range of up to 10 or 20 percent deviation. The carbon layer, for example a material of the carbon layer, may have a coefficient of thermal expansion of 1 ppm within a tolerance range of up to 10 or 20 percent deviation.

According to one specific embodiment, the copper layer and/or the carbon layer are/is situated in a recess of the printed circuit board, it being possible in particular for a level of the second main surface to correspond to a level of a copper layer surface of the copper layer and/or of a carbon layer surface of the carbon layer. The copper layer surface and/or the carbon layer surface may thus be situated in flush alignment with the second main surface.

The carbon layer may include at least one carbon fiber, in particular a ply containing multiple carbon fibers oriented in parallel. Such a carbon fiber may reinforce the carbon layer along a main length of extension of the carbon fiber. The carbon layer may also contain a plurality of the carbon fibers. These carbon fibers may be situated adjacent to one another and/or in parallel to one another.

The printed circuit board device may include at least one further carbon layer, which may be situated on a carbon layer surface of the carbon layer, it being possible in particular for at least one further carbon fiber of the further carbon layer to be situated extending perpendicularly or in parallel to the at least one carbon fiber of the carbon layer. The carbon layer may thus be situated between the printed circuit board and the further carbon layer. An overall thickness of the carbon layers, and thus the rigidity of the printed circuit board, may be increased via a plurality of carbon layers provided one on top of the other in this way. Similarly, the printed circuit board device may include a plurality of the described copper layers, which may be provided one on top of the other. At least one of the copper layers may be a copper foil.

A printed circuit board device according to the present invention, in which the at least one copper layer and/or carbon layer and/or further carbon layer may be incorporated into a duromer material. Such carbon fiber duromers are commercially available at a reasonable price, and have an extremely low coefficient of expansion of essentially 1 ppm.

The image sensor may be situated in a further recess of the printed circuit board, it being possible in particular for a level of a sensor main surface of the image sensor to correspond to a level of the first main surface. The sensor main surface may thus be situated in a plane with and/or in flush alignment with the first main surface. The image sensor may thus be protectively situated in the printed circuit board. In addition, mechanical decoupling of edge areas of the printed circuit board from an assembly area of the printed circuit board may be made possible, thereby allowing a reduction in the contribution of the edge areas to bending.

Additionally or alternatively, the printed circuit board may include at least one glass fiber layer and/or one aramide fiber layer. A fiber layer containing at least one aramide or polyaramide or aromatic polyaramide may be understood as an aramide fiber layer. Such a layer may also be used to reinforce or stabilize the printed circuit board.

An image capture module includes a printed circuit board device that is formed in one of the variants presented above. Such an image capture module may be used in a camera; on account of the printed circuit board device, a sharpness corridor of the image capture module may advantageously be provided, even in the event of thermal expansion and/or moisture.

A method for manufacturing a printed circuit board device for an image capture module for a camera is presented. The method includes at least a step of providing and a step of mounting. In the step of providing, a printed circuit board with a first main surface and a second main surface opposite from the first main surface, and an image sensor that is or may be situated on the first main surface of the printed circuit board are provided. In the step of mounting, at least one copper layer and/or carbon layer are/is mounted on the second main surface, the copper layer and/or carbon layer being designed to stabilize the printed circuit board.

This method may be implemented, for example, in a control unit, for example in software or hardware or in a mixed form of software and hardware.

The approach presented here also provides a device that is designed for carrying out, controlling, or implementing the steps of the method presented here in appropriate equipment. The object underlying the approach may also be quickly and efficiently achieved by this embodiment variant of the approach in the form of a device.

For this purpose, the device may include at least one processing unit for processing signals or data, at least one memory unit for storing signals or data, at least one interface to a sensor or an actuator for reading in sensor signals from the sensor or for outputting data and control signals to the actuator, and/or at least one communication interface for reading in or outputting data that are embedded in a communication protocol.

The processing unit may be, for example, a signal processor, a microcontroller, or the like, and the memory unit may be a flash memory, an EEPROM, or a magnetic memory unit. The communication interface may be designed for reading in or outputting data wirelessly and/or in a line-bound manner; a communication interface which may read in or output the line-bound data may read in these data electrically or optically, for example, from an appropriate data transmission line, or output same to an appropriate data transmission line.

In the present context, a device may be understood to mean an electrical device that processes sensor signals and outputs control and/or data signals as a function thereof. The device may include an interface which may have a hardware and/or software design. In a hardware design, the interfaces may be part of a so-called system ASIC, for example, which contains the most varied functions of the device. However, it is also possible for the interfaces to be dedicated, integrated circuits, or to be at least partially made up of discrete components. In a software design, the interfaces may be software modules which are present on a microcontroller, for example, in addition to other software modules.

Also advantageous is a computer program product or a computer program including program code which may be stored on a machine-readable medium or memory medium such as a semiconductor memory, a hard disk, or an optical memory, and used for carrying out, implementing, and/or activating the steps of the method according to one of the specific embodiments described above, in particular when the program product or program is executed on a computer or a device.

Exemplary embodiments of the approach presented here are illustrated in the figures and are explained in greater detail below.

### BRIEF DESCRIPTION OF THE DRAWINGS

FIG. 1 shows a schematic cross-sectional illustration of a printed circuit board with an image sensor.

FIGS. 2 through 3 each show a schematic cross-sectional illustration of an imager module together with a printed circuit board with an image sensor.

FIGS. 4 through 11 each show a schematic cross-sectional illustration of a printed circuit board device for an image capture module for a camera according to one exemplary embodiment.

FIGS. 12 through 13 show a perspective cross-sectional illustration of a carbon layer of a printed circuit board device according to one exemplary embodiment.

FIG. 14 shows a perspective illustration of a carbon layer of a printed circuit board device according to one exemplary embodiment.

FIG. 15 shows a perspective exploded illustration of an image capture module with a printed circuit board device according to one exemplary embodiment; and

FIG. 16 shows a flow chart of a method for manufacturing a printed circuit board device for an image capture module for a camera according to one exemplary embodiment.

### DETAILED DESCRIPTION OF EXAMPLE EMBODIMENTS

In the following description of advantageous exemplary embodiments of the present approach, identical or similar reference numerals are used for the elements having a similar action which are illustrated in the various figures, and a repeated description of these elements is dispensed with.

If an exemplary embodiment includes an “and/or” linkage between a first feature and a second feature, this is to be understood in such a way that according to one specific embodiment, the exemplary embodiment has the first feature as well as the second feature, and according to another specific embodiment, the exemplary embodiment either has only the first feature or only the second feature.

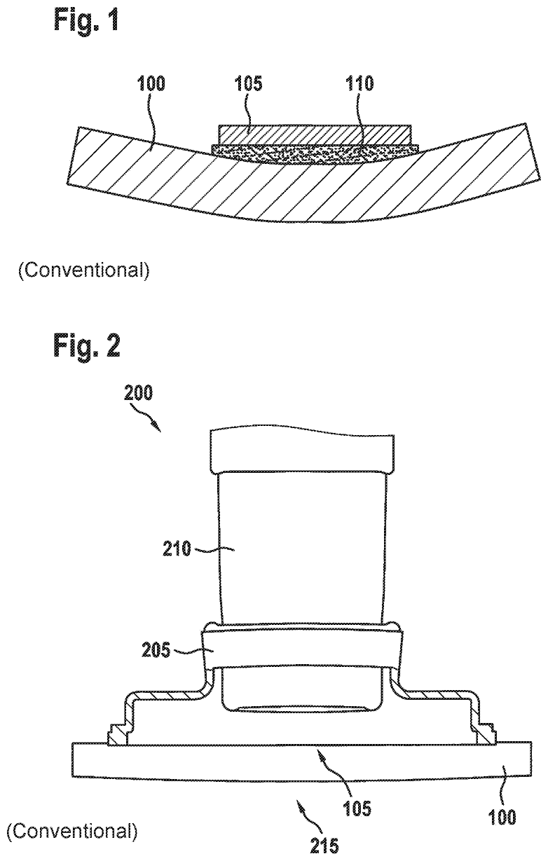

FIG. 1 shows a schematic cross-sectional illustration of a printed circuit board 100 with an image sensor 105. FIGS. 1 through 3 are used to illustrate a problem that is solved by the printed circuit board device presented in FIGS. 4 through 16.

FIG. 1 shows a conventional printed circuit board 100 (or PCB for short) that is glued to image sensor 105, which may also be referred to as a chip, with the aid of an adhesive 110. Strictly by way of example, circuit board 100 has a coefficient of thermal expansion of 25 ppm, adhesive 110 has a coefficient of thermal expansion of 50 ppm, and image sensor 105 has a coefficient of thermal expansion of 6 ppm.

Bending of printed circuit board 100 at high temperature, illustrated schematically here, is clearly apparent. Printed circuit board 100, which without a temperature influence would otherwise lie flatly in a plane, is now in a bent state under the high temperature. A middle area of printed circuit board 100 is situated bent downwardly, as the result of which image sensor 105, which is glued on in the middle area, is likewise situated moved downwardly in a plane, and is now situated in a depression in printed circuit board 100.

The printed circuit board device presented in FIGS. 4 through 16 advantageously prevents such bending of printed circuit board 100.

FIG. 2 shows a schematic cross-sectional illustration of an imager module 200 together with a printed circuit board 100 with an image sensor 105. This may be printed circuit board 100 with image sensor 105 described with reference to FIG. 1.

Conventional imager module 200 of a camera shown here is an image-recording unit that converts an optical signal into an electrical signal. Imager module 200 shown here includes printed circuit board 100 with image sensor 105, described with reference to FIG. 1, as well as a lens holder 205 and a lens 210. Lens holder 205 is the connecting element between lens 210, which generates an optical image, and image sensor 105. Printed circuit board 100 supports and contacts image sensor 105 as described with reference to FIG. 1. Lens holder 205 has a cup-shaped portion for covering printed circuit board 100 together with image sensor 105 and other electrical components, and a cylindrical portion to which lens 210 is joined. This cylindrical portion is also referred to as a tube.

A simulation result of imager module 200 at high temperature is shown. Printed circuit board 100 is in a warped state, as described with reference to FIG. 1, with middle area 215 of printed circuit board 100 illustrated bent away from lens 210.

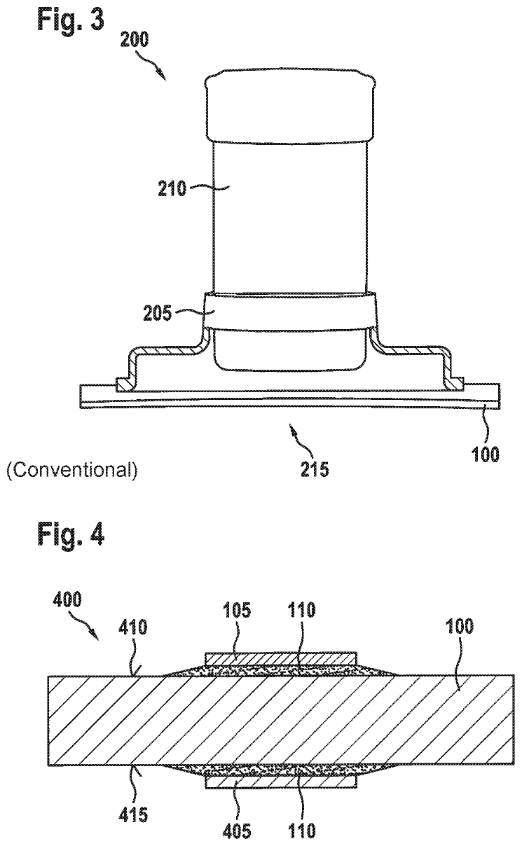

FIG. 3 shows a schematic cross-sectional illustration of an imager module 200 together with a printed circuit board 100 with an image sensor 105. This may be imager module 200 described with reference to FIG. 2, with the difference that a simulation result of imager module 200 at low temperature is illustrated. Here as well, printed circuit board 100 is in a warped state, with middle area 215 of printed circuit board 100 illustrated bent toward lens 210. Accordingly, the image sensor is likewise situated moved toward lens 210.

The printed circuit board device presented in FIGS. 4 through 16 advantageously prevents such bending of printed circuit board 100.

FIG. 4 shows a schematic cross-sectional illustration of a printed circuit board device 400 for an image capture module for a camera according to one exemplary embodiment.

Printed circuit board device 400 includes a printed circuit board 100, an image sensor 105, and at least one copper layer 405 and/or carbon layer. Printed circuit board 100 and image sensor 105 may be printed circuit board 100 with glued-on image sensor 105 described with reference to one of FIGS. 1 through 3. Printed circuit board 100 includes a first main surface 410 and a second main surface 415 opposite from first main surface 410. Image sensor 105 is situated, or according to one alternative exemplary embodiment is situatable, on first main surface 410 of printed circuit board 100. Copper layer 405 that contains copper at least in part, and/or the carbon layer that contains carbon at least in part, are/is situated on second main surface 415 and are/is formed to stabilize printed circuit board 100.

According to this exemplary embodiment, on second main surface 415 printed circuit board device 400 includes copper layer 405, which is glued to second main surface 415 with the aid of adhesive 110. First main surface 410 is situated extending in parallel to second main surface 415. Copper layer 405 is situated on a middle area of second main surface 415, opposite from image sensor 105. According to this exemplary embodiment, a formation or at least one dimension of image sensor 105 essentially corresponds to a formation or at least one dimension of copper layer 405. According to this exemplary embodiment, copper layer 405 has a coefficient of thermal expansion of 16 ppm. According to this exemplary embodiment, copper layer 405 is formed as a copper foil.

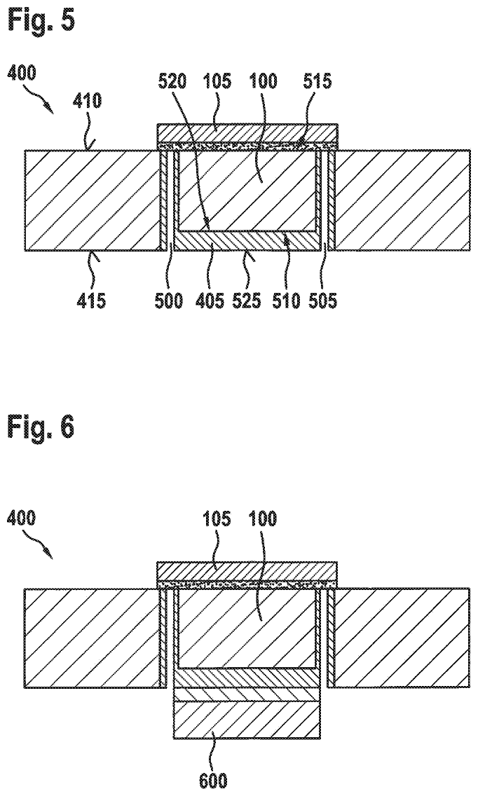

FIG. 5 shows a schematic cross-sectional illustration of a printed circuit board device 400 for an image capture module for a camera according to one exemplary embodiment. This may be printed circuit board device 400 described with reference to FIG. 4, with the difference that printed circuit board 100 includes at least one through opening 500, 505 and/or a recess 510.

Through opening 500 is formed extending from first main surface 410 to second main surface 415. According to this exemplary embodiment, a further through opening 505 is likewise formed extending from first main surface 410 to second main surface 415. According to this exemplary embodiment, a first intermediate section 515 of first main surface 410 between through opening 500 and further through opening 505 is at least partially contacted by image sensor 105. According to this exemplary embodiment, a second intermediate section 520 of second main surface 415 between through opening 500 and further through opening 505 is at least partially contacted by copper layer 405, and/or according to one alternative exemplary embodiment, by the carbon layer. According to this exemplary embodiment, through openings 500, 505 are situated extending in parallel to one another and oriented perpendicularly with respect to main surfaces 410, 415 of printed circuit board 100. According to this exemplary embodiment, a main length of the cross section of image sensor 105 shown here is larger than a distance between through opening 500 and further through opening 505. According to one exemplary embodiment, image sensor 105 at least partially covers at least one opening of through opening 500 and/or further through opening 505.

According to this exemplary embodiment, recess 510 is formed at second main surface 415. According to this exemplary embodiment, recess 510 is situated between through openings 500, 505. According to this exemplary embodiment, copper layer 405 and/or the carbon layer are/is situated in recess 510, according to this exemplary embodiment a level of second main surface 415 corresponding to a level of a copper layer surface 525 of copper layer 405 and/or of a carbon layer surface of the carbon layer. According to this exemplary embodiment, recess 510 is completely filled by copper layer 405, copper layer surface 525 being situated in flush alignment in a plane with sections of second main surface 415 of printed circuit board 100 situated outside recess 510.

Details of printed circuit board device 400 are described once again in greater detail below:

A current trend is an increase in a so-called field of view, i.e., a viewing angle of an image capture module, by values of +/−45°. Together with sharpness requirements such as a modulation transfer function >25% at small pixel dimensions between 3 and 5 μm, the lens provides a sharpness corridor in a range of 10 to 100 μm. A sharpness corridor means that, despite changes in temperature and/or moisture, image sensor 105 is mechanically always intended to be in this sharpness corridor, so that image sensor 105 is in a range of sufficiently high sharpness.

The lens holder, as a connecting element, sets this distance. In conventional imager modules such as the imager module shown in FIGS. 2 through 3, this results in a contribution to the following physical influences which destroys, or “consumes”, so to speak, the available sharpness corridor:

With increasing temperature, a thermal expansion of the lens holder results in an increasing distance. With increasing moisture, an absorption of moisture by the lens holder results in an increasing distance. With increasing temperature, a thermal expansion of the lens results in an increasing distance. With increasing moisture, an absorption of moisture by the lens results in an increasing distance. With increasing temperature, a thermal expansion of the adhesive results in an increasing distance. With increasing moisture, an absorption of moisture by the adhesive results in an increasing distance. A tolerance should be provided for a mounting process and material properties such as shrinkage. A difference between the thermal expansion of the printed circuit board and of the image sensor results in bending of the printed circuit board, with the image sensor moving away from the lens at high temperatures.

The individual contributions mentioned above all have the same algebraic sign. When conventional printed circuit boards are used, a sum of multiple or all of the stated individual contributions may result in a state in which there is a departure from the allowed sharpness corridor. However, when printed circuit board device 400 presented here is used, there is advantageously no departure from the sharpness corridor. The image sharpness thus advantageously remains sufficient for an image representation or image processing algorithms.

As an alternative to copper layer 405 and/or the carbon layer of printed circuit board device 400 presented here, it would be possible to reduce the contribution to the bending by merely achieving an increase in a thickness of printed circuit board 100, and thus an increase in the rigidity of printed circuit board 100. It would also be possible to mount a material such as a “dummy chip” made of silicon or ceramic, for example, having thermal properties similar to those of image sensor 105. However, in both of these cases high mechanical stresses would act on the adhesive. The reasons are the high elasticity coefficient, also referred to as the modulus of elasticity, of the printed circuit board material under pressure, and the rigidity of image sensor 105 in the form of the chip. In addition, the costs of the material for dummy chips with a processing operation, in the range of up to €0.20, would be very high compared to copper layer 405 and/or the carbon layer.

Printed circuit board device 400 presented here may also be referred to as a temperature-compensated imager printed circuit board.

According to this exemplary embodiment, one advantage of printed circuit board device 400 is that copper layer 405, with one or multiple copper plies, is situated beneath image sensor 105. According to this exemplary embodiment, another advantage of printed circuit board device 400 is the introduction of structures into printed circuit board 100 at the edge or beneath image sensor 105. These structures are through openings 500, 505 in the form of vias.

The advantage of printed circuit board device 400 is that the local elastic properties of printed circuit board 100 are changed, and an assembly area of image sensor 105 on printed circuit board 100 has a certain decoupling of the properties from the rest of printed circuit board 100. A temperature response may thus be greatly reduced, and even set in a targeted manner. This even goes so far as a negative temperature response being present; i.e., the algebraic sign of the bending is opposite from the above-mentioned case.

The vias locally weaken printed circuit board 100, so that according to one exemplary embodiment, at a high temperature bending develops solely beneath image sensor 105, and/or according to an alternative exemplary embodiment, when copper layer 405 has a coefficient of expansion higher than 16 ppm. According to the alternative exemplary embodiment, the edge area outside image sensor 105 attempts to maintain the original shape, and the contribution to defocusing is reduced. Vias represent a common process in printed circuit board manufacturing, and for a multilayer printed circuit board are present anyway. According to this exemplary embodiment, no bending develops beneath image sensor 105 at high temperature.

According to this exemplary embodiment, copper layer 405 beneath image sensor 105 has an expansion of 16 ppm. This reduces the bending in the area below the chip. Large copper plies reduce the bending. Both effects may be advantageously combined together with through openings 500, 505.

FIG. 6 shows a schematic cross-sectional illustration of a printed circuit board device 400 for an image capture module for a camera according to one exemplary embodiment. This may be printed circuit board device 400 described with reference to FIG. 5, with the difference that printed circuit board 100 does not include the recess, and printed circuit board device 400 includes no copper layer and instead includes the carbon layer. For a more detailed description of carbon layer 600, see FIGS. 12 through 14.

According to this exemplary embodiment, carbon layer 600 has a coefficient of thermal expansion of 1 ppm.

According to this exemplary embodiment, printed circuit board device 400 includes a material in the form of carbon layer 600 opposite from image sensor 105, in combination with the through openings. According to this exemplary embodiment, in an area beneath image sensor 105, the material mounted on the second main surface has a low coefficient of expansion. According to this exemplary embodiment, the material is a carbon fiber-filled duromer having a linear expansion of 1 ppm. Carbon fiber-filled duromers, also referred to as “CF duromers” for short, are a commercially available material. Fiber orientations of the carbon fiber-filled duromers may be advantageously specified.

According to this exemplary embodiment, carbon layer 600 is glued to the second main surface between the through opening and the further through opening. According to this exemplary embodiment, a main length of the cross section of carbon layer 600 shown here corresponds to a distance from through opening 500 to further through opening 505. According to this exemplary embodiment, carbon layer 600 is formed to be thicker than image sensor 105.

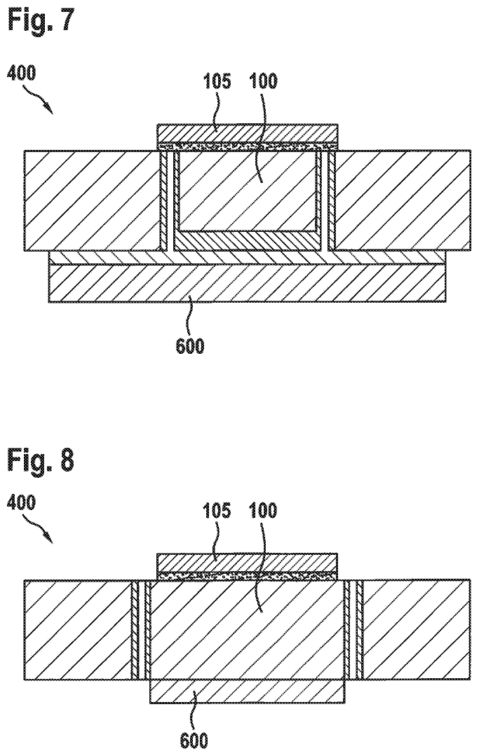

FIG. 7 shows a schematic cross-sectional illustration of a printed circuit board device 400 for an image capture module for a camera according to one exemplary embodiment. This may be printed circuit board device 400 described with reference to FIG. 6, with the difference that according to this exemplary embodiment, the main length of carbon layer 600 is greater than the main length of image sensor 105. According to one exemplary embodiment, carbon layer 600 at least partially covers at least one opening of the through opening and/or further through opening. According to this exemplary embodiment, the main length of carbon layer 600 is more than twice as great as the main length of image sensor 105. According to this exemplary embodiment, the main length of carbon layer 600 is 85 to 95 percent of a main length of printed circuit board 100, illustrated here in cross section.

FIG. 8 shows a schematic cross-sectional illustration of a printed circuit board device 400 for an image capture module for a camera according to one exemplary embodiment. This may be printed circuit board device 400 described with reference to FIG. 6, with the difference that according to this exemplary embodiment, the main length of image sensor 105 is shorter. According to this exemplary embodiment, the main length of image sensor 105 is shorter than the main length of carbon layer 600, illustrated here in cross section. According to this exemplary embodiment, the main length of image sensor 105 is up to 10 percent shorter than the main length of carbon layer 600.

According to this exemplary embodiment, the through openings in the form of vias are thus situated at an edge of the chip.

According to one alternative exemplary embodiment, carbon layer 600 is replaced by the copper layer.

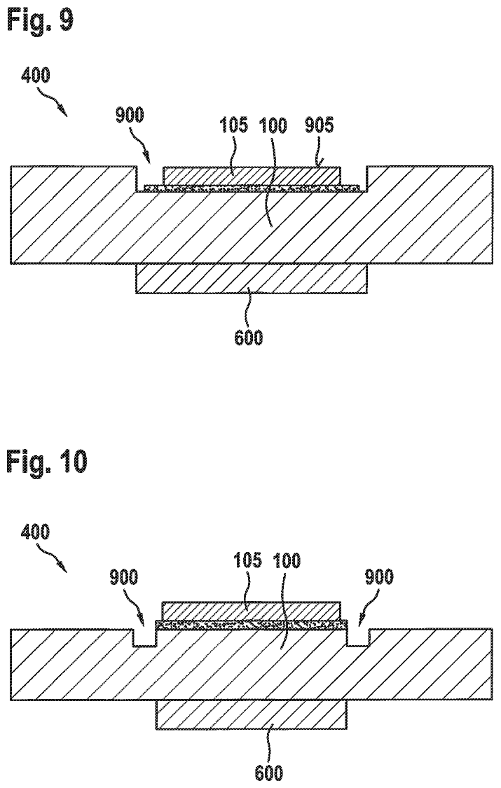

FIG. 9 shows a schematic cross-sectional illustration of a printed circuit board device 400 for an image capture module for a camera according to one exemplary embodiment. These may be one of printed circuit board devices 400 described with reference to preceding FIGS. 4 through 9, with the difference that according to this exemplary embodiment, printed circuit board device 400 includes no through opening, but does include a further recess 900.

According to this exemplary embodiment, image sensor 105 is situated in further recess 900 of printed circuit board 100, according to this exemplary embodiment a level of a sensor main surface 905 of image sensor 105 corresponding to a level of the first main surface.

According to this exemplary embodiment, image sensor 105 is situated entirely in further recess 900, sensor main surface 905 being situated in flush alignment in a plane, with sections of the first main surface of printed circuit board 100 situated outside further recess 900. According to this exemplary embodiment, a main length of image sensor 105, illustrated here in cross section, is shorter than a main length of further recess 900, illustrated here in cross section.

A formation of printed circuit board device 400 shown here may also be referred to as a stepped printed circuit board.

A mechanical decoupling of the edge areas from the assembly area of printed circuit board 100 together with image sensor 105 advantageously takes place via further recess 900. This results in a reduction in the contribution of the edge areas to the bending.

According to one alternative exemplary embodiment, carbon layer 600 is replaced by the copper layer.

FIG. 10 shows a schematic cross-sectional illustration of a printed circuit board device 400 for an image capture module for a camera according to one exemplary embodiment. This may be printed circuit board device 400 described with reference to FIG. 9, with the difference that according to this exemplary embodiment, image sensor 105 is not situated in further recess 900 of printed circuit board 100.

According to this exemplary embodiment, further recess 900 is implemented as a trench and/or a milled recess in the first main surface of printed circuit board 100 at the edge of image sensor 105. According to this exemplary embodiment, this trench is situated around image sensor 105, at least partially or around the entire circumference.

Due to this formation of further recess 900, a mechanical decoupling of the edge areas from the assembly area also takes place, resulting in a reduction in the contribution of the edge areas to the bending.

According to one alternative exemplary embodiment, carbon layer 600 is replaced by the copper layer.

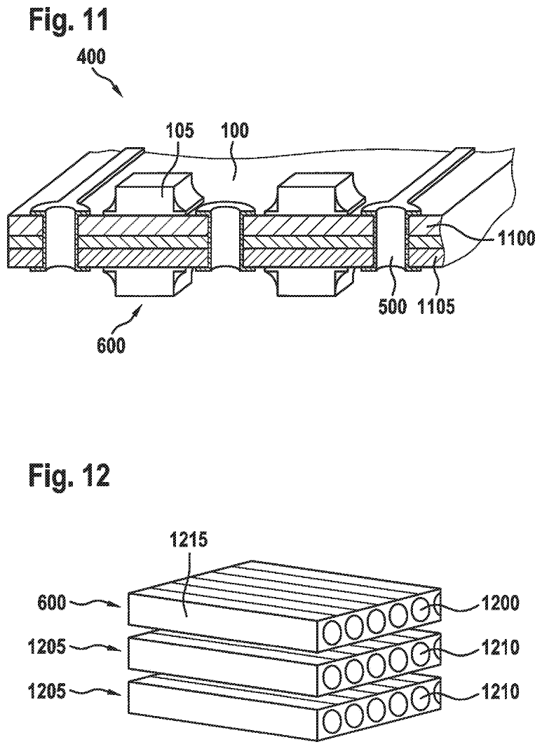

FIG. 11 shows a schematic cross-sectional illustration of a printed circuit board device 400 for an image capture module for a camera according to one exemplary embodiment. These may be printed circuit board devices 400 described with reference to one of FIGS. 5 through 10.

According to this exemplary embodiment, printed circuit board 100 includes at least one glass fiber layer 1100 and/or one aramide fiber layer 1105.

In other words, in printed circuit board device 400 shown here, aramide-based plies, also referred to as Kevlar-based plies, and glass fiber-based plies are used in the printed circuit board laminate.

According to this exemplary embodiment, printed circuit board 100 is designed as a multilayer printed circuit board made of an asymmetrically constructed laminate of glass fibers and aramide fibers. Situated between glass fiber layer 1100 and aramide fiber layer 1105 are copper plies, perpendicular to which through openings 500 in the form of vias are situated. According to this exemplary embodiment, glass fiber layer 1100 and aramide fiber layer 1105 have the same thickness and fiber orientation; therefore, the laminate is largely free of warping as the result of temperature. According to this exemplary embodiment, the aramide fibers of aramide layer 1105 are not conductive, and have a negative thermal expansion of −2 ppm to −3 ppm. With increasing temperature, an unassembled area of printed circuit board 100 will have warping, which counteracts the warping due to image sensor 105.

According to one alternative exemplary embodiment, carbon layer 600 is replaced by the copper layer.

FIG. 12 shows a perspective cross-sectional illustration of a carbon layer 600 of a printed circuit board device according to one exemplary embodiment. This may be carbon layer 600 described with reference to FIGS. 4 through 11.

According to this exemplary embodiment, carbon layer 600 includes at least one carbon fiber 1200. Strictly by way of example, according to this exemplary embodiment carbon layer 600 includes six of the carbon fibers 1200, which are situated adjacent to one another and extending in parallel to one another. According to this exemplary embodiment, printed circuit board device 400 also includes at least one further carbon layer 1205 situated on a carbon layer surface of carbon layer 600. According to this exemplary embodiment, at least one further carbon fiber 1210 of further carbon layer 1205 is situated extending in parallel to the at least one carbon fiber 1200 of carbon layer 600. According to this exemplary embodiment, printed circuit board device 400 includes two of further carbon layers 1205 with, for example, six each of further carbon fibers 1210, with all carbon fibers 1200, 1210 of the total three carbon layers 600, 1205 being situated extending in parallel to one another.

According to this exemplary embodiment, carbon layers 600, 1205 are situated in flush alignment, stacked one on top of the other.

According to this exemplary embodiment, at least one of carbon layers 600, 1205 is incorporated into a duromer material 1215. According to this exemplary embodiment, each of the three carbon layers 600, 1205 is incorporated into the duromer material 1215.

Carbon layers 600, 1205 may also be referred to as a unidirectional laminate, which has a high load capacity in the fiber direction and may be built up to a desired overall thickness.

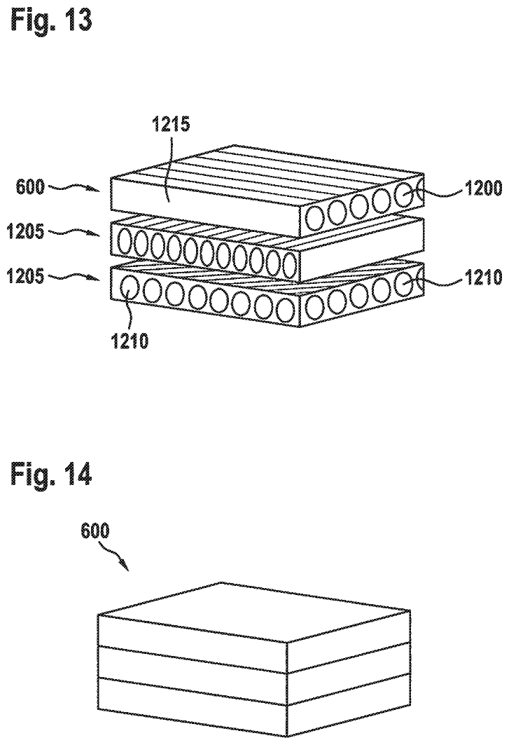

FIG. 13 shows a perspective cross-sectional illustration of a carbon layer 600 of a printed circuit board device 400 according to one exemplary embodiment. This may be carbon layer 600 with further carbon layers 1205 described with reference to FIG. 12, with the difference that according to this exemplary embodiment, at least one of further carbon fibers 1210 of one of further carbon layers 1205 is situated extending perpendicularly with respect to the at least one carbon fiber 1200 of carbon layer 600. According to this exemplary embodiment, all further carbon fibers 1210 of further carbon layer 1205, situated in the middle of the three carbon layers 600, 1205, are situated adjacent to one another and perpendicular to carbon fibers 1210 of carbon layer 600.

Details of carbon layers 600, 1205 are described once more in greater detail below:

Carbon layers 600, 1205 may also be referred to as a unidirectional laminate, which may accept load in multiple directions and may be built up to a desired overall thickness. According to this exemplary embodiment, a fiber direction of carbon fibers 1200, 1210 is or may be coordinated with a geometry of the printed circuit board for the image sensor. Duromer material 1215 is easily glueable, and may be machined using various cutting processes. Over a length of the duromer, which according to one exemplary embodiment extends beyond a contour of the image sensor, it is even possible to adjust the contribution of the areas outside the image sensor. Stepless temperature responses of the printed circuit board may be set in this way. Even the temperature behavior of the lens may thus be compensated for.

FIG. 14 shows a perspective illustration of a carbon layer 600 of a printed circuit board device according to one exemplary embodiment. These may be carbon layers 600 with the further carbon layers described with reference to FIGS. 12 through 13.

According to this exemplary embodiment, the three carbon layers 600 are pressed to one another and cured.

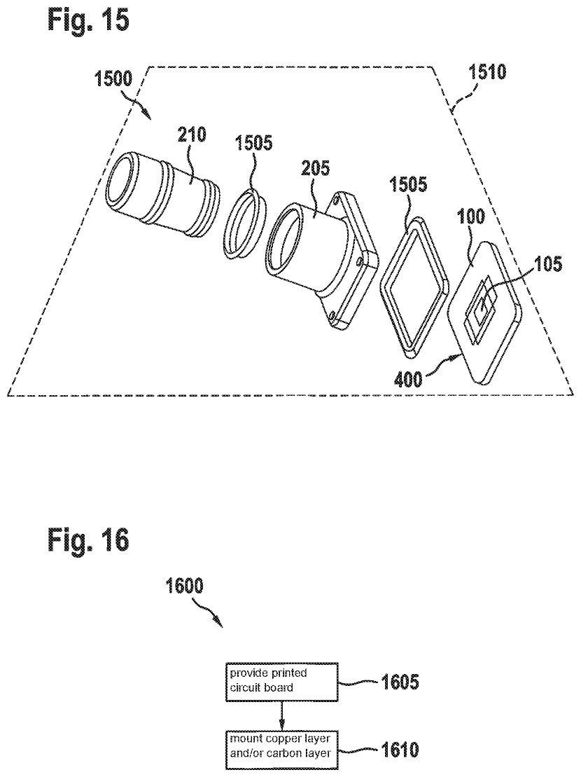

FIG. 15 shows a perspective exploded illustration of an image capture module 1500 with a printed circuit board device 400 according to one exemplary embodiment. Image capture module 1500 includes at least lens 210 and lens holder 205 described with reference to FIGS. 2 through 3, as well as one of the printed circuit board devices 400 described in one of FIGS. 4 through 14.

According to this exemplary embodiment, image capture module 1500 optionally includes two sealing elements 1505, it being possible to situate one of sealing elements 1505 between lens 210 and the tube of lens holder 205, and the other of sealing elements 1505 between the cup shape of lens holder 205 and printed circuit board 100.

Lens holder 205 is formed at least partially from plastic and/or metal. According to this exemplary embodiment, printed circuit board 100 is formed as a flexible printed circuit board on a stainless steel substrate, or as a so-called FR4 printed circuit board made from a flame-resistant and flame-retardant composite composed of epoxy resin and/or glass fiber fabric.

Image capture module 1500 presented here is formed for use in or with a camera 1510.

FIG. 16 shows a flow chart of a method 1600 for manufacturing a printed circuit board device for an image capture module for a camera. This may be one of the printed circuit board devices described with reference to one of FIGS. 4 through 15.

Method 1600 includes at least a step 1605 of providing and a step 1610 of mounting. In step 1605 of providing, a printed circuit board with a first main surface and a second main surface opposite from the first main surface, and an image sensor that is or may be situated on the first main surface of the printed circuit board are provided. In step 1610 of mounting, at least one copper layer and/or carbon layer are/is mounted on the second main surface, the copper layer and/or carbon layer being designed to stabilize the printed circuit board.

The method steps presented here may be carried out be repeatedly and in a different order than described.

What is claimed is:

1. A printed circuit board device for an image capture module for a camera, the printed circuit board device comprising:
a printed circuit board with a first main surface and a second main surface opposite from the first main surface;
an image sensor situated on the first main surface of the printed circuit board; and
at least one copper layer that contains copper at least in part, and/or a carbon layer situated on the second main surface and formed for stabilization of the printed circuit board.

2. The printed circuit board device as recited in claim 1, wherein the printed circuit board includes at least one through opening from the first main surface to the second main surface.

3. The printed circuit board device as recited in claim 2, wherein the printed circuit board includes at least one further through opening from the first main surface to the second main surface, a first intermediate section of the first main surface between the through opening and the further through opening being at least partially contacted by the image sensor, and/or a second intermediate section of the second main surface between the through opening and the further through opening being at least partially contacted by the copper layer and/or the carbon layer (600).

4. The printed circuit board device as recited in claim 1, wherein a first coefficient of expansion of the printed circuit board is greater than a second coefficient of expansion of the copper layer and/or the carbon layer.

5. The printed circuit board device as recited in claim 1, wherein the copper layer and/or the carbon layer is situated in a recess of the printed circuit board, a level of the second main surface corresponding to a level of a copper layer surface of the copper layer and/or of a carbon layer surface of the carbon layer.

6. The printed circuit board device as recited in claim 1, wherein the carbon layer includes at least one carbon fiber, the at least one carbon fiber having a ply with multiple carbon fibers oriented in parallel.

7. The printed circuit board device as recited in claim 6, including at least one further carbon layer that is situated on a carbon layer surface of the carbon layer, at least one further carbon fiber of the further carbon layer being situated extending perpendicularly or in parallel to the at least one carbon fiber of the carbon layer.

8. The printed circuit board device as recited in claim 1, wherein the at least one copper layer and/or the carbon layer is incorporated into a duromer material.

9. The printed circuit board device as recited in claim 1, wherein the image sensor is situated in a further recess of the printed circuit board, a level of a sensor main surface of the image sensor corresponding to a level of the first main surface.

10. The printed circuit board device as recited in claim 1, wherein the printed circuit board includes at least one glass fiber layer and/or one aramide fiber layer.

11. An image capture module with a printed circuit board device, the printed circuit board comprising:
a printed circuit board with a first main surface and a second main surface opposite from the first main surface;
an image sensor situated on the first main surface of the printed circuit board; and
at least one copper layer that contains copper at least in part, and/or a carbon layer situated on the second main surface and formed for stabilization of the printed circuit board.

12. A method for manufacturing a printed circuit board device for an image capture module for a camera, the method comprising the following steps:
providing a printed circuit board that includes a first main surface and a second main surface opposite from the first main surface, and an image sensor that is situated on the first main surface of the printed circuit board; and
mounting at least one copper layer and/or a carbon layer on the second main surface, the copper layer and/or the carbon layer being configured to stabilize the printed circuit board.

13. A device that is configured to carry out and/or control steps of a method for manufacturing a printed circuit board device for an image capture module for a camera, the method comprising the following steps:
providing a printed circuit board that includes a first main surface and a second main surface opposite from the first main surface, and an image sensor that is situated on the first main surface of the printed circuit board; and
mounting at least one copper layer and/or a carbon layer on the second main surface, the copper layer and/or the carbon layer being configured to stabilize the printed circuit board.

14. A non-transitory computer-readable storage device on which is stored a computer program for manufacturing a printed circuit board device for an image capture module for a camera, the computer program, when executed by a computer, causing the computer to perform the following steps:
providing a printed circuit board that includes a first main surface and a second main surface opposite from the first main surface, and an image sensor that is situated on the first main surface of the printed circuit board; and
mounting at least one copper layer and/or a carbon layer on the second main surface, the copper layer and/or the carbon layer being configured to stabilize the printed circuit board.
